(19) United States
(12) Patent Application Publication
(10) Pub. No.: US 2006/0266496 A1
(43) Pub. Date: Nov. 30, 2006

(54) Method and apparatus for dissipating heat

(75) Inventors: Brian J. Edward, Jamesville, NY (US); Peter J. Ruzicka, Auburn, NY (US)

Correspondence Address: BURR & BROWN, PO BOX 7068, SYRACUSE, NY, 13261-7068, US

(73) Assignee: SENSIS CORPORATION, East Syracuse, NY (US)

(21) Appl. No.: 11/303,326

(22) Filed: Dec. 15, 2005

Related U.S. Application Data
(60) Provisional application No. 60/685,855, filed on May 31, 2005.

(51) Int. Cl. H05K 7/20

(52) U.S. Cl. 165/80.3; 361/704; 165/905

(57) ABSTRACT

There is provided a heat dissipation device comprising a base, a base element positioned within the base, protrusions extending from the base, and protrusion elements positioned within the protrusions. Also provided are methods of dissipating heat, comprising passing fluid across and/or through such devices.

### FIELD OF THE INVENTION

The present invention relates to apparatus for dissipating heat. The present invention further relates to the thermal management of electronic components, and more particularly, limiting temperatures of components generating heat at very high density. The present invention further relates to methods of dissipating heat, e.g., from electronic components.

In preferred aspects, the present invention relates to apparatus for dissipating heat from electronic components, e.g., electronic components for a radar antenna.

### BACKGROUND OF THE INVENTION

Evolving electronic components are operating at higher speeds and higher power levels and are being packed more and more densely. As a consequence, these components are generating increasingly larger amounts of heat in smaller areas. To limit the temperatures of these components, and thereby realize peak performance plus reliable operation, this heat energy must be effectively removed.

The continued trend in digital electronic integrated circuits, such as computer processors, is to form more active devices (transistors) into smaller areas and to operate these devices at higher speeds. The by-product of this trend is the generation of very high heat densities. Removal of this heat has been identified as perhaps the biggest issue facing computer designers. Consequently, to support performance improvements, effective heat extraction techniques are essential. New transistor materials, such as silicon carbide, are being developed for both analog power and radio frequency (RF) devices. These materials enable generation, conversion, and management of much higher power levels than has been previously possible. Heat densities at the point of generation can be on the order of 7000 Watts per square millimeter peak, ten times the amount associated with current transistors. To fully realize the potential of these new material components, effective heat removal techniques are needed.

Opto-electronic components, such as laser diodes and photo-detectors, must be maintained within temperature bounds to operate properly. As their power levels increase, techniques for removal of their excess heat, so as to maintain preferred operational temperatures, are essential.

Next generation radar systems will be required to deliver high levels of performance and operational flexibility, feature exceptional reliability, and be amenable to growth in capability while being readily integrated into their host platforms. Active phased arrays afford significant radar performance capability while “tile” construct implementations yield minimum volume and weight systems, and effective air-cooling promotes reliable operation.

Phased arrays are configured from a plurality of individual radiating elements whose phase and amplitude states can be electronically controlled. The radiated energy from the collection of elements combines constructively (focused) so as to form a beam. The angular position of the beam is electronically redirected by controlling the elements' phases. The shape of the beam is altered by controlling both the elements' phases and amplitudes. Active phased array antennas include the initial low noise amplifier for receive and the final power amplifier for transmit with each individual radiator, in addition to the phase and amplitude control circuitry. These components are packaged into Transmit/Receive (T/R) modules and are distributed, with the radiating elements, over the array structure.

Tile array implementations package the phased array active circuits into low-profile modules which are disposed in a plane parallel to the radiating face of the array. This is in contrast to “brick” constructs which package the circuitry into higher profile modules which are disposed orthogonal to the face of the array. Tile construction yields relatively thin and hence low volume active phased arrays which are more readily adapted to the host platforms. The construction also results in minimizing weight, which is universally beneficial for all platforms.

### BRIEF SUMMARY OF THE INVENTION

The present invention provides thermally enhanced packages for high heat density electronic components which allow for extracting heat from extremely localized areas, effectively spreading this heat over a larger area, thereby decreasing its density, and efficiently transferring the heat to the equipment's cooling media. The package preferably incorporates a unique combination of high thermal conductivity and thermal-expansion matched materials. The high thermal conductivity of the materials (when provided) promotes heat conduction away from the components. The matched thermal expansion of the materials, to that of the components (when provided), minimizes the occurrences of the stresses in the components with temperature excursions.

In accordance with the present invention, there is provided a heat dissipation device comprising a base, a base element positioned within the base, protrusions extending from the base, and at least one protrusion element, each protrusion element being positioned within one of the protrusions, the base comprising a first material and the base element comprising a second material.

Each of the protrusions can independently and individually be of any desired shape. For example, representative suitable shapes for the protrusions include fins and pins. The devices according to the present invention can include protrusions of a variety of shapes, e.g., in representative examples, the protrusions in particular devices can consist of a plurality of fins, can consist of a plurality of pins, or can consist of a plurality of fins and a plurality of pins.

Any of the protrusions can, if desired, comprise a protrusion element. Any of the protrusion elements can, if desired, have one or more protrusion element vias. For example, in a device which includes one or more fins, a fin element can be positioned in each fin, and each fin element can have a plurality of fin element vias. Likewise, in a device which includes one or more pins, a pin element can be positioned in each pin, and each pin element can have a plurality of pin element vias. Similarly, in a device which includes one or more fins and one or more pins, a fin element can be positioned in each fin, each fin element can have a plurality of fin element vias, a pin element can be positioned in each pin, and each pin element can have a plurality of pin element vias.

The protrusions can independently and individually comprise any desired material. Preferably, the protrusions comprise the first material, i.e., the same material that the base comprises.

Where the device comprises one or more protrusion elements which comprise one or more protrusion element vias, the protrusion element vias can be filled with any desired material. Preferably, the protrusion element vias are filled with the same material that the protrusions comprise.

Alternatively or additionally, the base element can comprise one or more base element vias. The base element vias can, if desired, be filled with any suitable material, and preferably, the base element vias, when present, are filled with the first material (i.e., the same material that the base comprises).

Where the base element comprises one or more base element vias, each of the one or more base element vias is preferably substantially aligned with one of the protrusions.

Alternatively or additionally, the device can further comprise one or more heat transfer pieces positioned within the base.

Alternatively or additionally, the device can further comprise one or more high heat transfer slivers comprising, consisting essentially of and/or consisting of a material which provides high heat transfer properties, each of the one or more slivers each being positioned within one of the protrusions.

The present invention is further directed to methods of dissipating heat, comprising passing fluid (which can be gaseous or liquid, and which is preferably gaseous, a particularly preferred fluid being air) across protrusions of devices according to the present invention as described above.

A thermally enhanced package design according to the present invention preferably employs all solid-type materials, i.e., no internal fluids. There is no fundamental factor which limits either the heat loads or temperature ranges at which it functions. Preferably, the package design is compact and self-contained. The package design lends itself to production of electronic assemblies by being producible, and consequently affordable, using developed manufacturing processes. By contrast, alternative approaches for thermally enhancing electronic packaging have typically limited heat load and temperature ranges, are typically bulky and complex, and/or difficult to fabricate, rendering them costly.

The thermally enhanced packages according to the present invention enable insertion of new electronic component technologies into commercial and military systems with application to computers, transportation, communications, sensors, opto-electronics, and industrial controls. With this component packaging, systems using air-based cooling can be extended to higher power levels, deferring the need to transition to liquid coolant. For the highest power systems, the thermally enhanced packaging may also be advantageously employed with a liquid coolant media.

The invention may be more fully understood with reference to the accompanying drawings and the following detailed description of the invention.

### BRIEF DESCRIPTION OF THE DRAWING FIGURES

FIG. 1 is a front view of a heat dissipation device 10 according to an embodiment in accordance with the present invention.

FIG. 2 is a cross-sectional view taken along line 2-2 in FIG. 1.

FIG. 3 is a cross-sectional view taken along line 3-3 in FIG. 1.

FIG. 4 is a front view of the base element 21 in the heat dissipation device 10 shown in FIG. 1.

FIG. 5 is a cross-sectional view taken along line 5-5 in FIG. 1.

FIG. 6 is an exploded schematic view of an embodiment of a thermally enhanced package for use in conjunction with air coolant media.

FIG. 7 is a front perspective view of another embodiment of a heat transfer element according to the present invention.

FIG. 8 is a rear perspective view of the embodiment of a heat transfer element depicted in FIG. 7.

FIG. 9 is a cross-sectional view taken along line 9-9 in FIG. 4.

FIG. 10 is a front view of a base element of another embodiment of a heat dissipation device according to the present invention.

### DETAILED DESCRIPTION OF THE INVENTION

As noted above, in accordance with the present invention, there is provided a heat dissipation device comprising a base, a base element, protrusions and protrusion elements.

The base can comprise any suitable material. Preferably, the base comprises a material which readily transfers heat. In one aspect, the base can comprise a metal matrix composite, i.e., a material made by infusing (e.g., by melting and injecting) a metal into a porous pre-form. For example, a representative example of a preferred base is a base which comprises AlSiC, preferably in the form of a metal matrix composite. In a preferred aspect of the present invention, the base consists of and/or consists essentially of AlSiC, preferably in the form of a metal matrix composite.

As noted above, the base element is positioned within the base.

The base element can be formed from any suitable material, preferably a material which has an extremely high heat transfer coefficient. For example, an example of a particularly preferred material out of which the base element can be made is annealed pyrolytic graphite (APG).

The base and the base element can be configured in any suitable way. Preferably, the base has first and second sides which are substantially parallel with one another and the base element has first and second sides which are parallel with one another and which are also parallel with the first and second sides, respectively, of the base.

Preferably, the rate of heat transfer within the base element is greater in a direction parallel to a major surface of the base element than it is in a direction which is perpendicular to that surface of the base element.

Preferably, the base element comprises a plurality of base element vias. Preferably, base element vias, if provided, extend through the base element, but alternatively, they may extend through only a portion of the thickness of the base element. Where the base element includes base element vias, the base element vias can optionally be filled with any suitable material. Preferably, the base element vias, when present, are filled with the same material that the base comprises. Alternatively, the base element vias can be filled with any other suitable material, e.g., diamond slivers or carbon fiber slivers, or the base element vias can be partially filled with diamond slivers or carbon fiber slivers, with the remaining space being (1) unfilled, (2) filled with any desired material (e.g., the same material that the base comprises), or (3) partially filled with any desired material with the remainder being unfilled. Where the base element includes vias which are filled with the same material that the base comprises, heat transfer from the base element is enhanced. Where slivers are provided, such slivers can individually and independently be of any desired shape or shapes.

Where the base element comprises vias, the base element vias independently can extend in any desired direction or directions. Preferably, where the base element comprises base element vias, the base element vias each extend in a direction which is substantially perpendicular to a side (i.e., one of the major surfaces) of the base. Where the base element has base element vias, each of the base element vias is preferably substantially aligned with one of the protrusions.

The expression “aligned” as used herein, e.g., in the expression “each of the base element vias is substantially aligned with one of the protrusions” indicates that a plane substantially bisecting the protrusion (e.g., a fin) passes through the base element via from one side of the base element to the other side.

The expression “extends in a direction” when referring to a particular element, indicates that a line can be drawn in that direction which passes through that element.

The expression “fin” as used herein refers to a protrusion having two major dimensions and one minor dimension, preferably a structure which includes first and second substantially parallel sides.

As used herein, the term “substantially,” e.g., in the expressions “substantially aligned”, “substantially parallel”, “substantially bisecting”, and “substantially in a plane”, means at least about 90% correspondence (preferably 95% correspondence) with the feature recited, e.g., “substantially parallel” means that two planes diverge from each other at most by an angle of 10% of 90 degrees, i.e., 9 degrees (preferably 4.5 degrees); “substantially in a plane” means that a plane defined by any trio of points in the structure and a plane connecting any other trio of points in the structure define no angle greater than 10% of 90 degrees, i.e., 9 degrees (preferably 4.5 degrees).

The expression “substantially perpendicular”, as used herein, means that at least 90% (preferably 95%) of the points in the structure which is characterized as being substantially perpendicular to a reference plane are located on one of or between a pair of planes (1) which are perpendicular to the reference plane, (2) which are parallel to each other and (3) which are spaced from each other by a distance of not more than 10% (preferably 5%) of the largest dimension of the structure.

The expression “substantially linear”, as used herein, means that (1) a line connecting any pair of points which are both located in the portion of the plot which is substantially linear and which points are spaced by at least one fifth of the length of the portion of the plot, and (2) a line connecting any other pair of points in the portion of the plot which is substantially linear and which points are spaced by at least one fifth of the length of the portion of the plot, define an angle not greater than 9 degrees (preferably 4.5 degrees).

Preferably, the protrusions are fins, pins, or a combination of fins and pins. If desired, the protrusions can be shaped and arranged so as to assist in directing fluids relative to the heat dissipation device as desired.

The expression “pin” as used herein refers to a protrusion having one major dimension and two minor dimensions, the major dimension preferably extending substantially linearly.

Preferably, the protrusions comprise a material which is the same as or similar to a material that the base comprises. In a preferred aspect, the protrusions are made of the same material as the base.

Preferably, the protrusions are integral with the base. Alternatively, the protrusions can be attached to the base by any suitable method, a variety of which are well known to those of skill in the art, e.g., (1) by soldering, (2) by using an epoxy (preferably. a thermally conductive epoxy, e.g., an epoxy loaded with silver particles), (3) by S-bonding, and/or (4) by welding, all of these types of attachment methods being well known to those of skill in the art.

The protrusions can independently extend in any desired direction or directions from the base. Preferably, the protrusions each extend in a direction substantially perpendicular to a surface of the base. In a particularly preferred arrangement, the base has first and second sides, the protrusions comprise at least three fins, and each fin has first and second surfaces which are substantially perpendicular to the first side of the base.

Preferably, at least one protrusion element is positioned within each of at least one of the protrusions.

The protrusion elements independently and individually can be formed from any suitable material. Preferably, the protrusion elements are formed from a material (or materials) which has an (or which have) extremely high heat transfer coefficient(s). For example, an example of a particularly preferred material out of which the protrusion elements can be made is annealed pyrolytic graphite (APG). Other examples of materials out of which the protrusion elements can be made include carbon fiber and graphite. Preferably, the protrusion elements comprise a material which is the same as or similar to a material that the base element comprises. In a preferred aspect, the protrusion elements consist of the same material as the base element. Alternatively or additionally, some or all of the protrusions and/or the protrusion elements can comprise slivers made of any suitable material, e.g., diamond or carbon fiber. For example, the protrusions can comprise cylindrical pins and can each include a cylindrical diamond sliver (or a carbon fiber sliver) therewithin, or the protrusions can comprise fins and can each include a plurality of generally cylindrical or square cross-sectional diamond slivers (or carbon fiber slivers) therewithin. Optionally, some or all of the protrusion elements can extend into and through at least a portion of one or more base element vias.

Where the protrusions are fins, the fins can include protrusion elements which comprise fin elements which preferably each have a plurality of fin element vias. Preferably, fin element vias, if provided, extend through the respective fin element, but alternatively, they may extend through only a portion of the thickness of the fin element.

The protrusions preferably comprise a material which is the same as or similar to a material that the base comprises, and in a preferred aspect, the protrusions are made of the same material as the base. Where the protrusions have protrusion element vias, the protrusion element vias are preferably at least partially filled with a material which comprises a material which is the same as or similar to the material that the base comprises, and are preferably filled with the same material out of which the base is made. Alternatively, the protrusion element vias can be filled with any other suitable material, e.g., they can be at least partially filled with diamond slivers and/or carbon fiber slivers. By providing a device in which the protrusion element vias are filled with the same material out of which the protrusions are made, heat transfer from the protrusion elements is enhanced.

Where the protrusions element vias are provided, the protrusion element vias can independently extend in any desired direction or directions. Where the device has fins and the fins have fin element vias, the fin element vias of each fin preferably extend in a direction substantially perpendicular to a surface of the fin in which the fin element vias are provided.

Preferably, at least one electronic component (e.g., an integrated circuit component) is mounted on a side of the base which is opposite to the side on which the protrusions are provided.

Preferably, the device further comprises one or more heat transfer pieces positioned within the base. A heat transfer piece, when provided, preferably has an extremely high heat transfer coefficient. Preferably, one or more heat transfer pieces are provided in a region of the base adjacent to a location or locations where high heat loads are expected, e.g., adjacent to a position on the base opposite to the protrusions on which an IC component which generates large amounts of heat is to be mounted.

Preferably, a heat transfer piece, when present, extends through the base element.

The heat transfer piece can, if desired, extend through almost the entire thickness of the base, in order to increase the heat conductivity through the thickness of the base. In many cases, it is desirable for the heat transfer piece to not extend to (or beyond) one or both of the surfaces of the base, e.g., when protrusions are to be attached to the base to facilitate attaching (for example, by soldering) such protrusions to the base.

A heat transfer piece or pieces, when provided, can be made of any suitable material, a particularly preferred example being diamond. Alternatively, the heat transfer piece or pieces can be formed of any other suitable material, e.g., an SiC plug with diamond deposited on its surface (e.g., by chemical vapor deposition). The one or more heat transfer pieces, when provided, can be of any desired size and/or shape.

The heat dissipation devices according to the present invention, and each component thereof, can be of any desired overall size and/or shape, and may include any desired number of protrusions.

The present invention is further directed to methods of dissipating heat, comprising passing fluid (preferably gaseous, a particularly preferred fluid being air) across protrusions of devices according to the present invention as discussed above. As mentioned above, however, the fluid can alternatively comprise liquid coolant.

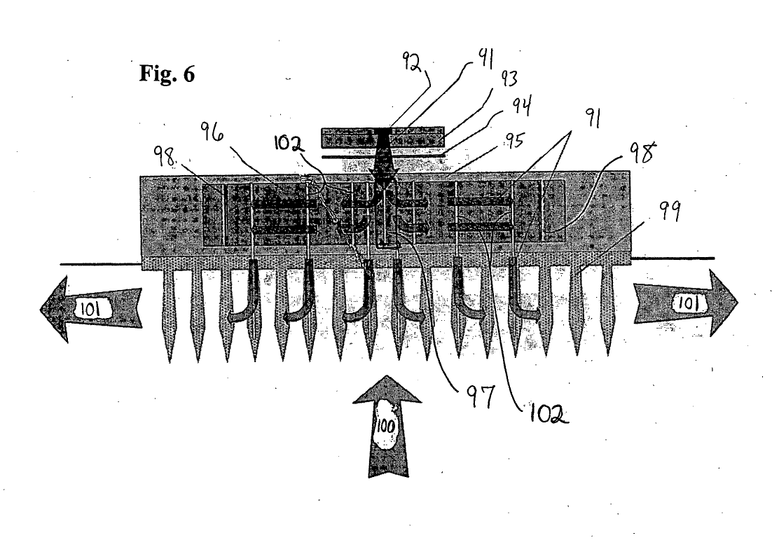

FIG. 6 depicts an embodiment of a thermally enhanced electronics package in accordance with the present invention in its application to components in their die or “chip” state, i.e., solid-state transistors or integrated circuits at their silicon, silicon carbide, gallium arsenide, etc. substrate material level. FIG. 6 shows a baseline package design. A single die is depicted, although the design is equally applicable for packaging multiple dies. Heat 91 generated at the transistor area 92 is conducted through the substrate material 93 to its bottom side.

Heat density is highest at the transistor area and can be, e.g., on the order of 7000 Watts peak, 1000 to 2000 Watts average per square millimeter for silicon carbide RF transmitter parts used in radar systems. Depending on the transistor type and its material composition, temperature at this heat origination area is to be limited to 125 to 175° C. for achieving high performance and reliable operation.

The substrate material thickness is typically minimized so as to limit the temperature gradient through it. For the above-referenced silicon carbide transmitter parts, the thickness may be on the order of 100 microns. Silicon carbide itself has a relatively high thermal conductivity of 160 W/mK. The die is attached to the thermally enhanced package by a metal solder 94 such as a gold-tin alloy. In many cases, solders are preferable to epoxy adhesives, as their thermal conductivity, approximately 55 W/mK, is typically on the order of 20 times higher than that of conductive epoxies. Alternatively, any other die attach methods can be employed, a variety of which are well known to those skilled in the art.

The thermally enhanced package is comprised of aluminum silicon carbide (AlSiC) metal matrix composite 95 having an embedded heat spreader 96, 97. AlSiC features a high thermal conductivity of 200 W/mK, can be net-shape cast to accommodate die recesses and other package features, has a tailorable coefficient of thermal expansion (by composition of the AlSiC mix) to match that of the die, can capture electrical/RF feed-through features, and supports hermeticity. The embedded heat spreader is a combination of industrial diamond heat transfer pieces 97 placed through a sheet of annealed pyrolytic graphite (APG) material 96. APG features exceptional heat spreading properties having an in-plane (X-Y) thermal conductivity of 1350 to 1550 W/mK. The cross-plane (Z-axis) conductivity is comparatively rather low, only 10 to 20 W/mK. The diamond heat transfer pieces, however, have an extremely high isotropic conductivity of 1200 W/mK. Inserting the heat transfer pieces through the APG thereby provides a low impedance path for vertical conduction of heat 91 from under the die and into the high conductivity planes of the APG. The heat in the APG is now spread over a sufficient area to enable transfer into the electronic equipment's cooling media. The quantity of industrial diamond heat transfer pieces may be economized by featuring them most densely directly beneath the die and less so away from the die. Vertical conductivity through the APG may be additionally augmented by forming vias 98 through it and filling the vias 98 (partially or completely) with a material which has favorable heat conduction properties, preferably the same material that the base comprises (e.g., AlSiC). These vias are formed integral to the metal matrix package. The embodiment depicted in FIG. 6 further includes diamond slivers 102 which extend into the protrusions 99.

FIG. 6 illustrates the thermally enhanced packing adapted for air cooling. Heat exchanging protrusions 99 are formed on the base of the AlSiC package. Making the protrusions integral to the package is preferable to attaching them as a separate part as the thermal impedance of such an interface is avoided. The inlet coolant air 100 may flow in the plane of the heat exchanger or impinge normal to the heat exchanger as depicted in FIG. 6. Normal impingement is preferred as it promotes more effective heat transfer from the protrusions to the air. The coolant air, now containing the heat which originated at the die, is exhausted to the package sides 101.

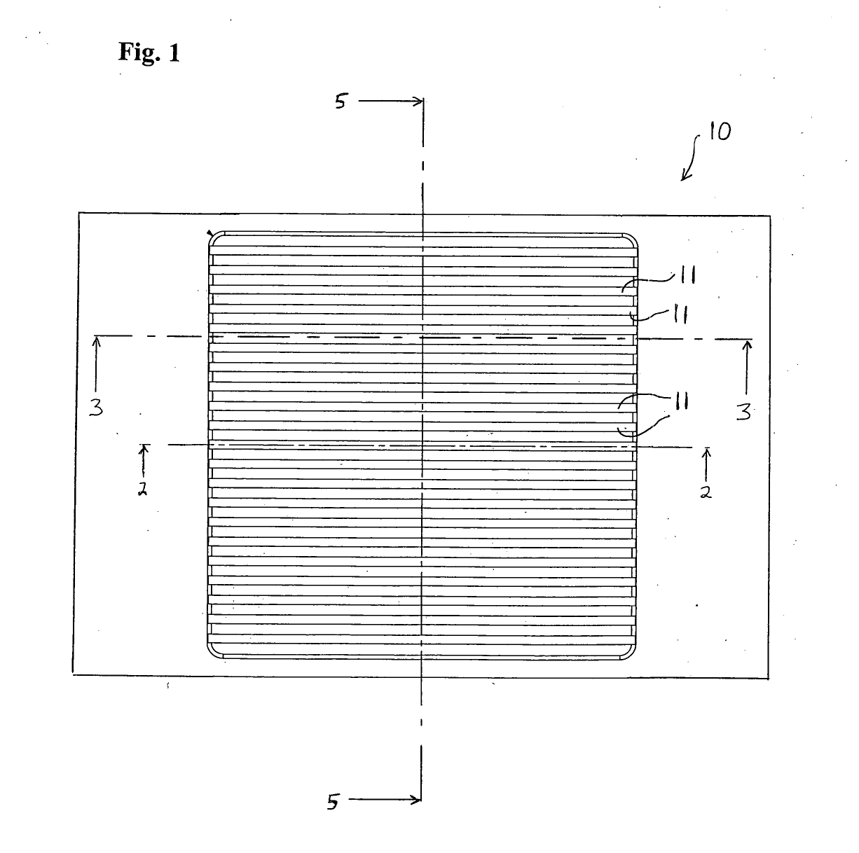

An embodiment of a heat dissipation device according to the present invention is depicted in FIGS. 1-5.

FIG. 1 is a front view of the heat dissipation device 10 according to the embodiment depicted in FIGS. 1-5. The heat dissipation device 10 includes a plurality of protrusions 11 (in this case, the protrusions 11 are fins).

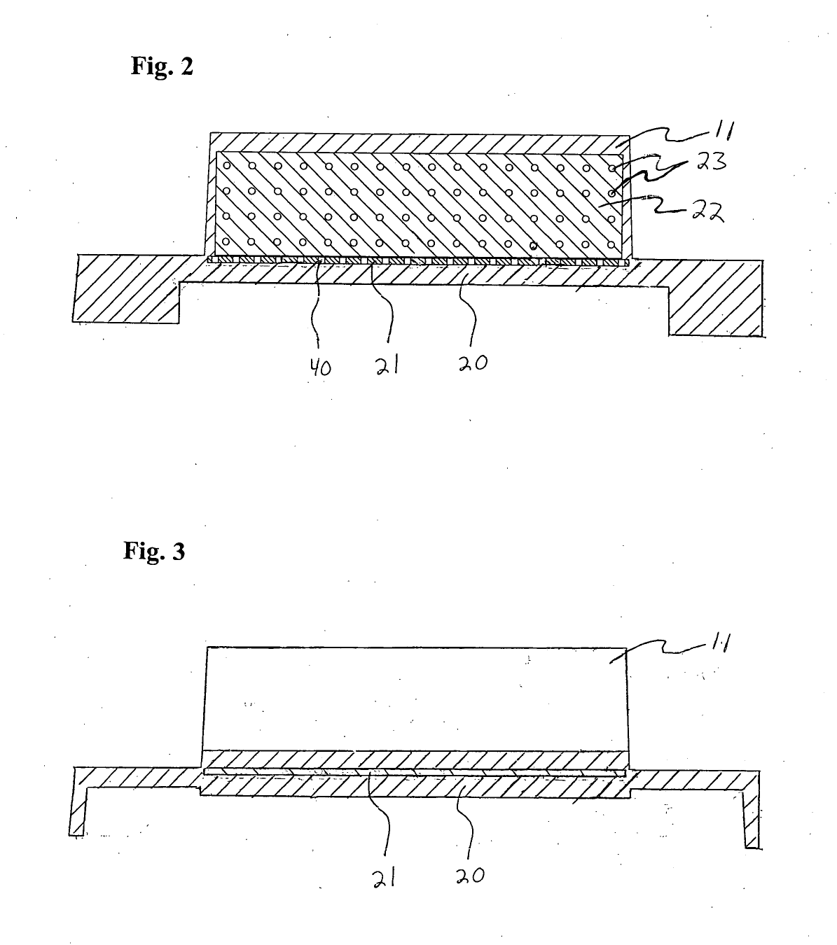

FIG. 2 is a cross-sectional view of the heat dissipation device 10 shown in FIG. 1 taken along line 2-2 in FIG. 1. FIG. 2 shows the base 20 of the heat dissipation device 10, as well as a protrusion element 22 (in this case, a fin element) positioned within one of the fins 11. The protrusion element 22 includes a plurality of protrusion element vias 23. FIG. 2 also depicts the base element 21 positioned within the base 20.

FIG. 3 is a cross-sectional view of the heat dissipation device 10 taken along line 3-3 in FIG. 1, through a plane in which no protrusion 11 is present. Accordingly, from the view shown in FIG. 3, only the base 20 and the base element 21 are seen in cross-section.

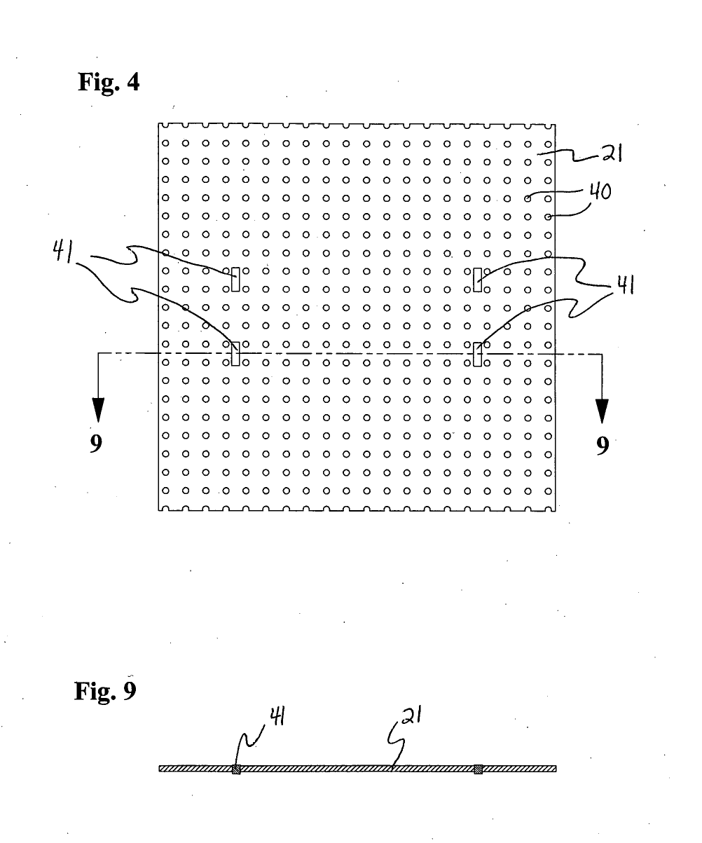

FIG. 4 is a front view of the base element 21 in the heat dissipation device 10. FIG. 4 shows the base element 21 and a plurality of base element vias 40 formed in the base element 21. FIG. 4 also shows four heat transfer pieces 41. FIG. 9 is a cross-sectional view taken along the line 9-9 in FIG. 4. FIG. 9 shows that the heat transfer pieces 41 extend through the base element 21.

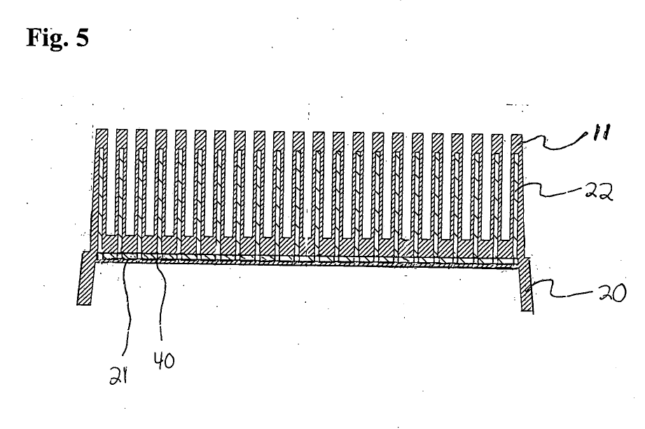

FIG. 5 is a cross-sectional view of the heat dissipation device 10 taken along line 5-5 in FIG. 1. From FIG. 5, it can be seen that the protrusion elements 22 are aligned with base element vias 40 in the base element 21.

In the embodiment shown in FIGS. 1-5, the base 20 and the fins 11 are integral and are formed of AlSiC, while the protrusion elements 22 and the base element 21 are formed of APG. The protrusion element vias 23 and the base element vias 40 are filled with AlSiC. The heat transfer pieces 41 are formed of diamond.

IC components are mounted on the base 20 on the rear side thereof, i.e., on the side opposite the front side as shown in FIG. 1. The IC components can be mounted in any desired orientation. Preferably, the regions of greatest heat intensity are located opposite the heat transfer pieces 41 relative to the base 20. The rear side of the base 20 can be configured in any desired orientation in order to accommodate the IC components which are mounted thereon, e.g., the rear side of the base 20 can be in the form of a “quad pack”, such “quad packs” being well known in the art.

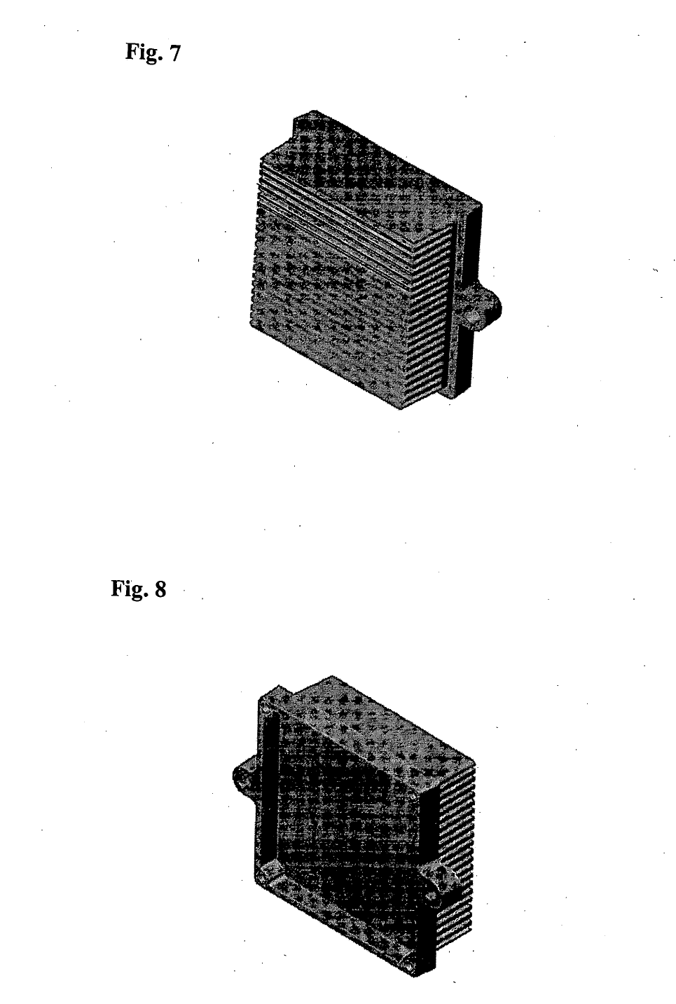

FIG. 7 is a front perspective view of another embodiment of a heat transfer element according to the present invention.

FIG. 8 is a rear perspective view of the embodiment of a heat transfer element depicted in FIG. 7.

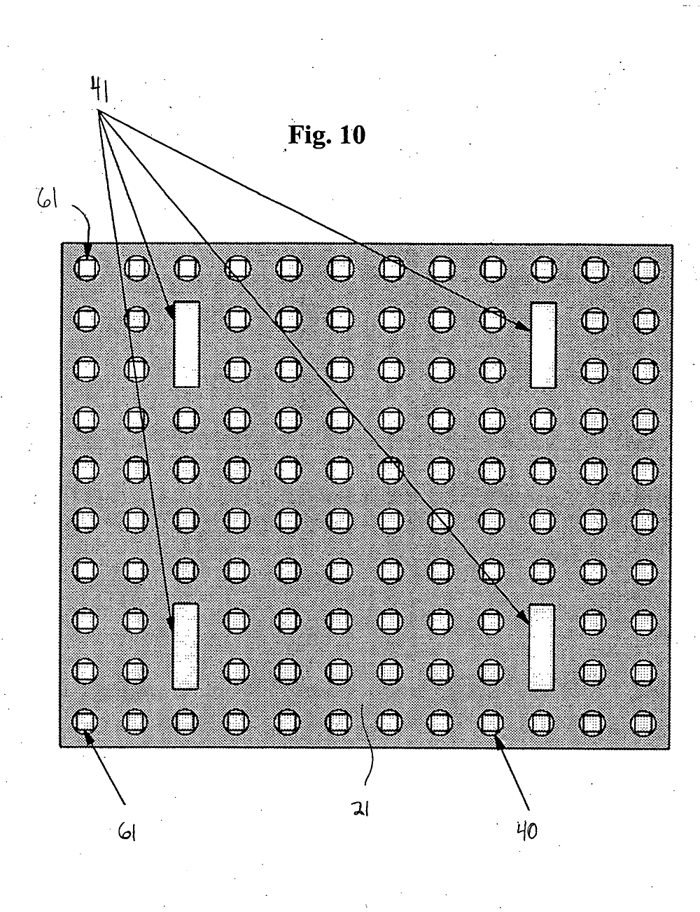

FIG. 10 depicts a front view of a base element of another embodiment of a heat dissipation device according to the present invention. The embodiment depicted in FIG. 10 is similar to the embodiment depicted in FIGS. 1-5, except that in the embodiment depicted in FIG. 10, additional diamond slivers 61 (i.e., in addition to the diamond heat transfer pieces 41) are positioned in the base element vias 40. In this embodiment, the diamond slivers 61 extend into the fins (alternatively, the diamond slivers 61 could not extend into the fins). Also, as can be seen in FIG. 10, the diamond slivers 61 have square cross-sections, and they do not completely fill the base element vias 40 (alternatively, the diamond slivers 61 can be of any other shape, e.g., they can be cylindrical, and they can optionally completely fill one or more of the base element vias 40, and/or in cases where the diamond slivers 61 do not completely fill the base element vias 40, rather than the remaining spaces being empty, such remaining spaces can be partially or completely filled with any suitable material or materials).

Any two or more structural parts of the devices described herein can be integrated. Any structural part of the devices described herein can be provided in two or more parts which are held together, if necessary. Similarly, any two or more functions can be conducted simultaneously, and/or any function can be conducted in a series of steps.

1. A heat dissipation device, comprising:
a base, said base comprising a first material;
a base element positioned within said base, said base element comprising a second material;
a plurality of protrusions extending from said base; and
a plurality of protrusion elements, each said protrusion element being positioned within a respective one of said protrusions,
said base element comprising a plurality of base element vias, said base element vias being filled with base element via filler material, said base element via filler material comprising said first material.

2. A device as recited in claim 1, wherein each said protrusion is a fin.

3. A device as recited in claim 1, wherein each said protrusion is a pin.

4. A device as recited in claim 1, wherein:
said base has a base first side and a base second side,
said base first side extends substantially in a base first side plane,
said plurality of protrusions comprises at least a first protrusion, a second protrusion and a third protrusion,
said first protrusion, said second protrusion and said third protrusion each extend from said base first side,
said first protrusion has a first protrusion first surface and a first protrusion second surface,
said first protrusion first surface extends substantially in a first protrusion first surface plane,
said first protrusion first surface plane is substantially perpendicular to said base first side plane,
said first protrusion second surface extends substantially in a first protrusion second surface plane,
said first protrusion second surface plane is substantially parallel to said first protrusion first surface plane,
said second protrusion has a second protrusion first surface and a second protrusion second surface,
said second protrusion first surface extends substantially in a second protrusion first surface plane,
said second protrusion first surface plane is substantially parallel to said first protrusion second surface plane,
said second protrusion second surface extends substantially in a second protrusion second surface plane,
said second protrusion second surface plane is substantially parallel to said second protrusion first surface plane,
said third protrusion has a third protrusion first surface and a third protrusion second surface,
said third protrusion first surface extends substantially in a third protrusion first surface plane,
said third protrusion first surface plane is substantially parallel to said second protrusion second surface plane,
said third protrusion second surface extends substantially in a third protrusion second surface plane, and
said third protrusion second surface plane is substantially parallel to said third protrusion first surface plane.

5. A device as recited in claim 1, wherein:
said base has a base first side and a base second side,
said base first side extends substantially in a base first side plane,
said base second side extends substantially in a base second side plane,
said base second side plane is substantially parallel to said base first side plane,
said base element has a base element first side and a base element second side,
said base element first side extends substantially in a base element first side plane,
said base element second side extends substantially in a base element second side plane,
said base element first side plane is substantially parallel to said base first side plane, and
said base element second side plane is substantially parallel to said base second side plane.

6. A device as recited in claim 1, wherein each of said protrusion elements has a plurality of protrusion element vias.

7. A device as recited in claim 6, wherein:
said base has a base first side,
said plurality of protrusions comprises at least a first protrusion and a second protrusion,
said first protrusion and said second protrusion extend from said base first side,
said first protrusion has a first protrusion first surface which extends substantially in a first protrusion first surface plane, and
each of said protrusion element vias extends in a direction substantially perpendicular to said first protrusion first surface plane.

8. A device as recited in claim 1, wherein:
each of said protrusions comprises said first material,
each of said protrusion elements has a plurality of protrusion element vias, and
each of said protrusion element vias is filled with protrusion element via filler material, said protrusion element via filler material comprising said first material.

9. A device as recited in claim 1, wherein said first material comprises a metal matrix composite.

10. A device as recited in claim 1, wherein said first material is AlSiC.

11. A device as recited in claim 1, wherein each said protrusion element comprises said second material, and said second material is annealed pyrolytic graphite.

12. A device as recited in claim 1, wherein:
said base element has a base element first surface which extends substantially in a base element first surface plane, and
said base element has a base element heat transfer rate in a direction which is parallel to said base element first surface plane which is greater than a base element heat transfer rate in a direction which is perpendicular to said base element first surface plane.

13. A device as recited in claim 1, further comprising at least a first heat transfer piece positioned within said base.

14. A device as recited in claim 13, wherein at least said first heat transfer piece extends through said base element.

15. A device as recited in claim 13, wherein at least said first heat transfer piece comprises diamond.

16. A device as recited in claim 1, wherein each of said base element vias is substantially aligned with one of said protrusions.

17. A device as recited in claim 1, wherein:
said base has a base first side which extends substantially in a base first side plane,
each of said base element vias extends in a direction substantially perpendicular to said base first side plane.

18. A device as recited in claim 1, wherein:
said base has a base first side and a base second side,
said protrusions extend from said base first side, and
at least one electronic component is mounted on said base second side.

19. A device as recited in claim 1, further comprising at least one sliver extending into at least one of said protrusions.

20. A device as recited in claim 19, wherein said sliver comprises at least one material selected from the group consisting of diamond and carbon fiber.

21. A device as recited in claim 1, further comprising at least one sliver positioned in at least one of said protrusions.

22. A device as recited in claim 21, wherein said sliver comprises at least one material selected from the group consisting of diamond and carbon fiber.

23. A device as recited in claim 1, wherein said second material is annealed pyrolytic graphite.

24. A heat dissipation device, comprising:
a base, said base comprising a first material;
a base element positioned within said base, said base element comprising a second material;
a plurality of protrusions extending from said base; and
a plurality of protrusion elements, each said protrusion element being positioned within a respective one of said protrusions,
each of said protrusion elements comprising a plurality of protrusion element vias,
said protrusion element vias being filled with protrusion element via filler material, said protrusion element via filler material comprising said first material.

25. A device as recited in claim 24, wherein:
said base has a base first side and a base second side,
said base first side extends substantially in a base first side plane,
said plurality of protrusions comprises at least a first protrusion, a second protrusion and a third protrusion,
said first protrusion, said second protrusion and said third protrusion each extend from said base first side,
said first protrusion has a first protrusion first surface and a first protrusion second surface,
said first protrusion first surface extends substantially in a first protrusion first surface plane,
said first protrusion first surface plane is substantially perpendicular to said base first side plane,
said first protrusion second surface extends substantially in a first protrusion second surface plane,
said first protrusion second surface plane is substantially parallel to said first protrusion first surface plane,
said second protrusion has a second protrusion first surface and a second protrusion second surface,
said second protrusion first surface extends substantially in a second protrusion first surface plane,
said second protrusion first surface plane is substantially parallel to said first protrusion second surface plane,
said second protrusion second surface extends substantially in a second protrusion second surface plane,
said second protrusion second surface plane is substantially parallel to said second protrusion first surface plane,
said third protrusion has a third protrusion first surface and a third protrusion second surface,
said third protrusion first surface extends substantially in a third protrusion first surface plane,
said third protrusion first surface plane is substantially parallel to said second protrusion second surface plane,
said third protrusion second surface extends substantially in a third protrusion second surface plane, and
said third protrusion second surface plane is substantially parallel to said third protrusion first surface plane.

26. A device as recited in claim 24, wherein:
said base has a base first side and a base second side,
said base first side extends substantially in a base first side plane,
said base second side extends substantially in a base second side plane,
said base second side plane is substantially parallel to said base first side plane,
said base element has a base element first side and a base element second side,
said base element first side extends substantially in a base element first side plane,
said base element second side extends substantially in a base element second side plane,
said base element first side plane is substantially parallel to said base first side plane, and
said base element second side plane is substantially parallel to said base second side plane.

27. A device as recited in claim 24, wherein said base element comprises a plurality of base element vias.

28. A device as recited in claim 24, wherein:
said base has a base first side,
said plurality of protrusions comprises at least a first protrusion and a second protrusion,
said first protrusion and said second protrusion extend from said base first side,
said first protrusion has a first protrusion first surface which extends substantially in a first protrusion first surface plane, and
each of said protrusion element vias extends in a direction substantially perpendicular to said first protrusion first surface plane.

29. A device as recited in claim 24, wherein said second material is annealed pyrolytic graphite.

30. A device as recited in claim 24, wherein each of said protrusion elements comprises said second material, and said second material is annealed pyrolytic graphite.

31. A device as recited in claim 24, wherein:
said base element has a base element first surface which extends substantially in a base element first surface plane, and
said base element has a base element heat transfer rate in a direction which is parallel to said base element first surface plane which is greater than a base element heat transfer rate in a direction which is perpendicular to said base element first surface plane.

32. A device as recited in claim 24, further comprising at least a first heat transfer piece positioned within said base.

33. A device as recited in claim 32, wherein at least said first heat transfer piece extends through said base element.

34. A device as recited in claim 33, wherein at least said first heat transfer piece comprises diamond.

35. A device as recited in claim 27, wherein each of said base element vias is substantially aligned with one of said protrusions.

36. A device as recited in claim 27, wherein:
said base has a base first side which extends substantially in a base first side plane,
each of said base element vias extends in a direction substantially perpendicular to said base first side plane.

37. A device as recited in claim 24, wherein:
said base has a base first side and a base second side,
said protrusions extend from said base first side, and
at least one electronic component is mounted on said base second side.

38. A device as recited in claim 24, further comprising at least one sliver extending into at least one of said protrusions.

39. A device as recited in claim 38, wherein said sliver comprises at least one material selected from the group consisting of diamond and carbon fiber.

40. A device as recited in claim 24, further comprising at least one sliver extending into at least one of said protrusions.

41. A device as recited in claim 40, wherein said sliver comprises at least one material selected from the group consisting of diamond and carbon fiber.

42. A device as recited in claim 24, wherein said first material comprises a metal matrix composite.

43. A device as recited in claim 24, wherein said first material is AlSiC.

44. A device as recited in claim 24, wherein each said protrusion is a fin.

45. A method of dissipating heat, comprising:
passing fluid across protrusions,
said protrusions extending from a base of a heat dissipation device,
said base comprising a first material,
said heat dissipation device further comprising:
a base element positioned within said base, said base element comprising a second material; and
a plurality of protrusion elements, each said protrusion element being positioned within a respective one of said protrusions,
said base element comprising a plurality of base element vias, said base element vias being filled with base element via filler material, said base element via filler material comprising said first material.

46. A method as recited in claim 45, wherein said fluid is gaseous.

47. A method as recited in claim 45, wherein said fluid is air.

48. A method as recited in claim 45, wherein said protrusions comprise pins.

49. A method as recited in claim 45, wherein each said protrusion is a fin.

50. A method of dissipating heat, comprising:
passing fluid across protrusions,
said protrusions extending from a base of a heat dissipation device,
said base comprising a first material,
said heat dissipation device further comprising:
a base element positioned within said base, said base element comprising a second material; and
a plurality of protrusion elements, each said protrusion element being positioned within a respective one of said protrusions,
said protrusion elements comprising a plurality of protrusion element vias, said protrusion element vias being filled with protrusion element via filler material, said protrusion element via filler material comprising said first material.

51. A method as recited in claim 50, wherein said fluid is gaseous.

52. A method as recited in claim 50, wherein said fluid is air.

53. A method as recited in claim 50, wherein each said protrusion is a fin.
